(19) United States
(12) Patent Application Publication
(10) Pub. No.: US 2014/0295105 A1
(43) Pub. Date: Oct. 2, 2014

(54) METHOD AND DEVICE FOR DEPOSITING SILICON ON A SUBSTRATE

(71) Applicants: Michael Huth, Usingen (DE); Andreas Terfort, Halstenbek (DE)

(72) Inventors: Michael Huth, Usingen (DE); Andreas Terfort, Halstenbek (DE)

(21) Appl. No.: 13/996,441

(22) PCT Filed: Dec. 23, 2011
(86) PCT No.: PCT/EP11/06543

§ 371 Date: Sep. 10, 2013

(30) Foreign Application Priority Data
Dec. 23, 2010 (DE) 10 2010 0550564.9

(51) Int. Cl. C23C 16/448; C23C 16/48

(52) U.S. Cl. CPC C23C 16/4488; C23C 16/487
USPC 427/585; 427/255.28; 118/715

(57) ABSTRACT

The invention relates to a method and a device for depositing silicon on a substrate using a focused beam of charged particles. A precursor containing silicon is provided, said precursor being dissociated by the beam in the immediate vicinity of the substrate. The aim of the invention is to allow the deposition of silicon on a substrate in a particularly effective way, material-protecting and precise manner. For this purpose, polysilane is used as the precursor.

The invention refers to a method of depositing silicon onto a substrate by using a focused beam of charged particles, where a silicon-containing precursor is provided, which is being dissociated by the beam in direct proximity to the substrate. In addition, the invention refers to a corresponding device.

Methods of depositions, for example silicon depositions on a substrate (SiO₂, AU etc.) have utility in many areas of microelectronics and related fields, but also in the areas directed to applied or basic research. Different methods are known for the deposition of materials (diamond layers, silicon-containing layers, tin oxide layers), for example chemical vapor phase deposition methods (CVD, Chemical vapor Deposition) or, also electron beam-based vapor deposition (EB-CVD, Electron Beam Chemical Vapor Deposition). The latter method is also termed as EBID (Electron Beam Induced Deposition or—when utilizing an ion beam as IBID (Ion Beam Deposition or IB-CVD). An additional normally used term for methods of this type is FPBID (Focused particle Beam Deposition).

During chemical vapor phase deposition, the substrate is normally heated to temperatures of several hundred degrees Celsius. From one or more of the reactants, solid components are deposited through chemical reactions from the vapor phase that are then deposited onto the substrate.

In the electron beam-based vapor deposition, a precursor is provided in direct proximity to the substrate, that is, essentially at its surface, from which by use of a focused electron beam, a solid component, for example silicon is deposited. Such a method could also be conducted through ion beams, which can be generated for example through a ion fine-jet installation.

With the two afore-described methods, deposition on the surface of the substrate can essentially be made for either two-dimensional or 3-dimensional structures.

From the article “Si deposition by electron beam induced surface reaction” by S. Matsui and M. Mito, Appl. Phys. Lett. 53 (16), 17 Oct. 1988, an electron beam-based vapor deposition method for the deposition of silicon on a substrate is known, where a silicon-containing precursor dichlorosilane (SiH₂Cl₂) is utilized. The depositions, according to the authors, contain 1.9 at-% chlorine.

The use of chlorine-containing precursors and in particular, SiH₂CL₂ has the drawback that the unintentional, but normally not avoidable inclusion of chlorine atoms in the deposition degrade the electrical properties of the deposition. In addition, the chlorine atoms can react with the aqueous portion of the residual vapor still residing in the reaction chamber, for example to form HCl and thus have a unintentional corrosive effect on the substrate and thereby damages the substrate. Furthermore, the free chlorine, due to its reactivity, can damage the deposition device itself (corrosion).

It is thus an aspect of the invention to provide a method for realizing a direct deposition of silicone on a substrate, which is especially effective and material-gentle and can be carried out in a precise manner. In addition, a device suitable for that purpose should also be provided.

Thus, with respect to the method according to the present invention, polysilicone is used as a precursor.

Further features of the present invention are the subject of the dependent claims.

The invention starts with the notion that the properties of silicone depositions on substrates have to be adapted to the increasing demands for modern applications. The demands refer in particular the conductivity, the structural size and the purity of the deposition. In addition, no damages or impurities should occur during the process of deposition.

To realize these demands, it is necessary that the silicone is directly deposited onto the substrate without the use of a lithographic mask technique. To this end, the silicone should be directly deposited by means of a particle beam induced dissociation of a precursor onto the substrate. In addition, a suitable precursor should be utilized in order to realize the highest quality of the silicone deposits. The precursor should be free of chlorine, since chlorine, due to its highly corrosive property, can damage the deposit and the substrate.

As has been now established, a precise, pure and gentle on the material silicone deposition is realized by utilizing a silicone containing precursor form the class of polysilanes, or a precursor containing polysilane. Polysilanes are free of chlorine, thus avoiding the corrosive effect of chlorine on the substrate and the deposit. Polysilanes also comprise chemical structures that can be precisely dissociated by a focused and charged particle beam and thus are able to realize a precise deposition of the silicone. The precursor molecules that are adsorbed at the surface of the substrate through different inelastic processes (i.e. “dissociative electron attachment”) are being dissociated into lasting and volatile components. The lasting components form the silicone deposit.

In a preferred embodiment of the method, the precursor neopentasilane (Si₅H₁₂) is utilized. Neopentasilane is free of chlorine, so that the highly corrosive effect of chlorine which occurs when using chlorine containing precursors is thus completely eliminated and at room temperature exhibits a vapor pressure favorable for the deposition process, preferably in the range of 0.1-100 mbar.

Further polysilanes that are utilized advantageously as precursors are cylic, branched and linear silanes (SiₙHₘ) to n=7, for example linear pentasilane (Si₅H₁₂) and linear hexasilane (Si₆H₁₄). These two polysilanes are free of chlorine, they are liquid at room temperature and at room temperature exhibit an advantageous vapor pressure for EBID/IBID methods.

An especially precise deposition, or a deposition with high spatial dissociation, in particular, in direction lateral to the substrate is realized by the use of an electron beam. In an alternative implementation of the method, the particle beam can consist of ions, for example Ga⁺-Ions. The use of such ion beams leads normally to a doping of the deposit.

In order to arrange localized deposits according to structural requirements on a substrate, the particle beam is advantageously moved for scanning across the deposit. Through the scanning and, preferably, the repeating motions across the substrate surface or across the already existing deposit, two-dimensional or three-dimensional structures can be created.

When using an electron beam, scanning of this type is advantageously created with the aid of a scanning electron microscope (SEM) for generating the electron beam. The lateral resolution of the method in this case is determined by the resolution capacity of the scanning electron microscope. Hereby, the exit area of the secondary electrons from the surface of the substrate in the surrounding of the beam focus must also be considered. At typical beam energies from 5 to 15 keV and currents around 100 pA, minimal structural widths of 10 to 20 nm or less are realized with high resolution microscopes. When using focused ion beams, scanning is preferably carried out with a scanning ion microscope. Thereby, structural sizes of 30 nm can be realized.

Providing or delivering the precursors to the surface of the substrate is carried out advantageously through a vapor injection system by which the precursor can be provided in target-directed manner in the area of the surface of the substrate, and where the deposit should be placed, which normally is the focus of the electron or ion beam.

Advantageously, the method is carried out at room temperature. The vapor pressure of neopentasilane at room temperature and of other, afore-stated polysilanes, are in a favorable range for FPBID processes. As a result, the deposition of silicon at room temperature is without any problems. Also, heating the substrate for the precursor is not necessary.

The method as described is advantageously applied to repair masks in lithographic processes. EUV masks (EUV=Extreme Ultra Violet) are prepared with electromagnetic radiation at wave lengths in the “distant” or extreme UV or X-ray range at 13.5 nm. Due to the very low transmission rate for the usual brand substrates, costly radiation treatments through the use of reflection is required. In order to compensate for the low reflectivity of single material layers at those wavelengths, multiple layers or multi-layered systems are used which function as Bragg's interferential mirror. According to the prior art, Mo—Si layer pairs are used that are repeated 40-50 times.

In this connection, a considerable problem lies already in the production of large surfaced mask structures that are free of defects. Defects can occur for example due to contamination from particles in the air, abrasion from manual systems or also the formation of crystals at the mask surface. The critical size of the defect is thereby below 30 nm, which is why only highest resolution corrective measures can work. A high resolution Si/MO—SI-EBID process can thus be advantageously applied not only in repairing masks that are already in use, but can be applied also on quality control and retro-improvements of already existing masks. The repair of Cr-based masks in conventional lithography at wave lengths in the range of 193 nm and ArF-excimer lasers as light source from EBID of Cr-based structures and electron beam-induced reactive etching is commercially applied for example by NaWoTec GmbH, an enterprise taken over by Carl Zeiss SMT AG.

The described method is advantageously carried out for editing of switching circuits. Further areas of application are in the areas directed to applied research and basic research.

With respect to the device, one of the aspects of the present invention is the use of a polysilane as a precursor. In a preferred variant of the device the precursor is a neopentasilane. Advantageously a scanning electron microscope is used as particle beam device.

The advantages that are realized with the present invention are in particular, the use of a silicone-containing precursor of the class of poly silanes in an EBID/IBID method, a direct deposition of silicone with high accuracy and resolution and few impurities. In particular, when using neopentasilane as a precursor, which at room temperature is in liquid form and which possesses a favorable vapor pressure for the EBID/IBID method, the silicone of great purity is easily deposited and without any inclusion of chlorine. With a guided (scanned or continuous) and repetitive motion of the particle beam across the substrate, a precise two-dimensional and three-dimensional deposit is produced.

An embodiment of the invention is shown in the drawings and is described in more detail. The very schematic illustration shows in:

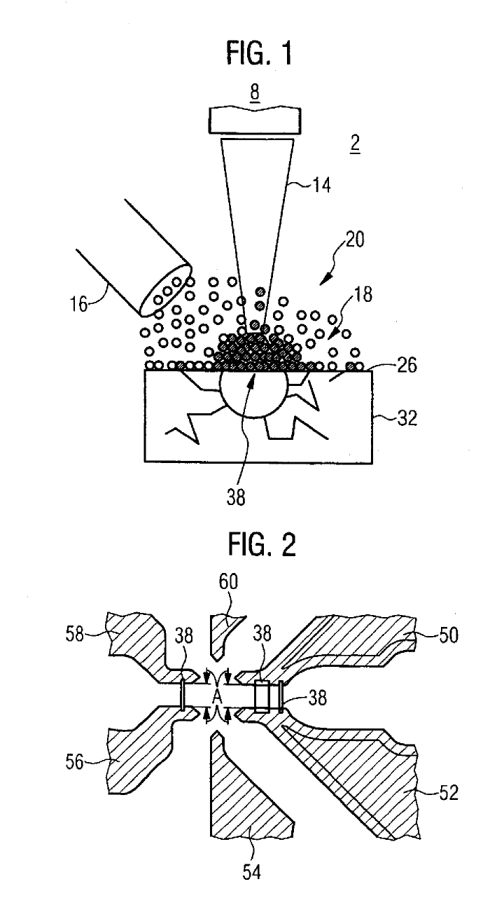

FIG. 1 a device for the deposition of silicone onto a substrate with the aid of a precursor of the class of polysilane and with a particle beam device and a vapor injection system in a preferred embodiment;

FIG. 2 three examples of deposited Si between metallic contact structures, and,

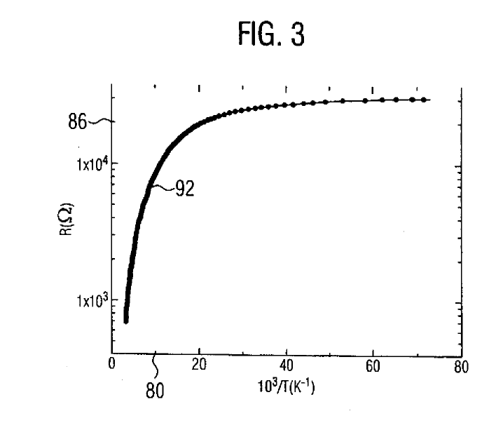

FIG. 3 temperature dependence of the electric conductivity of a typical deposit produced by means of the device of FIG. 1.

Identical structures in all figures are designated with the same numerals.

The device 2 as illustrated in FIG. 1 for the direct deposition of silicone includes a particle beam device 8 that generates an electron beam 14. In the present embodiment, the particle beam device 8 is configured as a scanning electron microscope. Through a vapor injection system 16, a precursor 20 is provided in an area 18 at the surface 26 of the substrate 32 in which the deposition of the silicone is to be made. The precursor 20 containing silicone is disassociated by the beam 14 and the secondary processes originated by the beam 14 at the surface 26 of the substrate 32. Hereby, two components are generally generated from the precursor, a volatile components and a solid component. The solid component is the deposit 38. This should contain an as high as possible portion of silicone in order to exhibit a good electrical conductivity. Through the repeated guided motions of the beam 14 across the surface 26 or across the already existing deposit 38, the desired structure—also three-dimensional ones—is deposited.

In the present embodiment, neopentasilane (Si₅H₁₂) is used as precursor 20. Neopentasilane is carbon-free Si-precursor 20 which is liquid under ambient conditions. Upon disassociation of the precursor, a solid phase silicone is produced for deposited onto the substrate 32, and the volatile hydrogen-containing phase. At room temperature, the vapor pressure of neopentasilane is in a range favorable for FPBID-processes. Thus, growth rates of about at least 0.01 μm³/min are realized. In comparison to these values, the gaseous precursor SiH₂Cl₂ exhibits a much higher vapor pressure, so that it is expected that the adhesion coefficient is very low and the corresponding growth rate markedly lower than if neopentasilane were used.

Typical deposits that are realized with the device 2 consist of at least 87 at-% silicone, with portions of carbon (C) and oxygen (O) in the range of 5 to 7 at-%. This can be detected, for example, through the use of energy-dispersive X-ray analysis (EDX). The described impurities are the result of the residual gas compounds in the vacuum of the electron microscope during the described processes of the Si-deposition. These can be almost or completely eliminated by improving the vacuum.

In addition, with the device according to the present invention and the corresponding method, a deposition of silicone at a (moderately) heated (<100° C.) substrate is possible.

In FIG. 2, various contact structures 50, 52, 54, 56, 58, 60 are shown in a light microscopic image, where between the contact structures 50, 52 and the contact structures 56, 58 each Si-depositions 38 were prepared. The distance A between the contact structures 50, 52 and 56, 58 are each 20 μm.

In FIG. 3, the temperature dependency of the electric conductivity of a typical, deposition 38 carried out with the device of FIG. 1, is illustrated. At the abscissa 80, the inverse temperature T⁻¹ in unit K⁻¹ multiplied by factor 1000 is shown, while the ordinate 86 shows the electric resistance R in unit Ohm (Ω). The curve 92 shows behavior that is typical for amorphous silicone. For the charge transport, also local conditions are especially contributing below the conductivity band lower margin of the silicone, which phenomenon is also identified as trap-controlled carrier contribution. Phenomenologically is is possible to model this through a distribution of activation energies. Due to the high hydrogen content of the precursor 20 neopentasilane, it can be assumed that the non-linked Si-bonds are saturated to a great extent with hydrogen (a-Si:H). In view of an increased long term stability of a-Si:H, it is known that C— additions have a positive effect. However, these have a negative effect upon the mobility of the charge carrier.

### NUMERAL LIST

2 device
8 particle beam device
14 beam
16 gas injection system
18 area
20 precursor
26 surface
32 substrate
38 deposit
50 contact structure
52 contact structure
54 contact structure
56 contact structure
58 contact structure
60 contact structure
80 abscissa
86 ordinate
92 curve

1.-10. (canceled)

11. A method of depositing silicone onto a substrate comprising the steps of,
providing a substrate and a silicone-containing precursor, generating a focused beam of charged particles for acting on the silicone-containing precursor,
bringing the focused particle beam in direct proximity to the substrate to induce dissociation of the silicone-containing precursor and to thereby realize deposition of the silicone onto the substrate, wherein said precursor is a polysilane.

12. The method of claim 11, wherein the precursor is neopentasilane.

13. The method according to claim 11, wherein the charged particles are electrons.

14. The method according to claim 11, wherein the charged particles are ions.

15. The method according to claim 11, wherein the beam is scanned across the substrate.

16. The method according to claim 15, wherein the beam is generated and moved by a scanning electron microscope.

17. The method according to claim 11, wherein the precursor is provided by a vapor injection system.

18. The method according to claim 11, wherein the deposition is carried out at room temperature.

19. A device for the deposition of silicone onto a substrate comprising a particle beam device for producing a beam of charged particles and a vapor injection system to provide a silicone-containing precursor, wherein after the silicone-containing precursor is dissociated by the particle beam, silicone is deposited onto the substrate, wherein the precursor is a polysilane.

20. The device according to claim 19, wherein the precursor is neopentasilane.
